(19) United States
(12) Patent Application Publication
(10) Pub. No.: US 2025/0228147 A1
(43) Pub. Date: Jul. 10, 2025

(54) MEMORY STRUCTURE

(71) Applicant: TAIWAN SEMICONDUCTOR MANUFACTURING COMPANY, LTD., Hsinchu (TW)

(72) Inventors: Fu-Ting Sung, Hsinchu (TW); Hsia-Wei CHEN, Hsinchu (TW); Yu-Wen LIAO, Hsinchu (TW); Chang-Ming WU, Hsinchu (TW); Shih-Chang LIU, Hsinchu (TW); Wen-Ting CHU, Hsinchu (TW)

(73) Assignee: TAIWAN SEMICONDUCTOR MANUFACTURING COMPANY, LTD., Hsinchu (TW)

(21) Appl. No.: 18/409,163

(22) Filed: Jan. 10, 2024

(51) Int. Cl. H10N 70/00; H10B 63/00

(52) U.S. Cl. CPC H10N 70/841; H10B 63/80; H10N 70/063

(57) ABSTRACT

A memory structure includes a substrate, a barrier layer, an etch stop layer, a bottom electrode, a data storage feature and a top electrode. The substrate has a metal trench. The barrier layer is disposed over the metal trench. The etch stop layer surrounds the barrier layer, and, together with the barrier layer, completely covers the metal trench. The bottom electrode is disposed over the barrier layer. The data storage feature is disposed over the bottom electrode. The top electrode is disposed over the data storage feature.

### BACKGROUND

Semiconductor memory devices are widely used in integrated circuits (ICs) to store digital data for electronic applications. Various types of memory, such as magnetoresistive random access memory (MRAM), resistive random access memory (RRAM), ferroelectric random access memory (FeRAM), or the like, have been developed for data storage purposes and have advantageous characteristics of high speed, high power efficiency, good scalability, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view illustrating a memory structure in accordance with a first embodiment.

FIG. 2 is a sectional view illustrating a memory structure in accordance with a second embodiment.

FIG. 3 is a sectional view illustrating a memory structure in accordance with a third embodiment.

FIG. 4 is a sectional view illustrating a comparison between the memory structures in accordance with the first embodiment and the third embodiment.

FIG. 5 is a flow chart illustrating a method for fabricating a memory structure in accordance with some embodiments.

FIG. 6 through FIG. 11 are sectional views that cooperate with FIG. 5 to illustrate the method for fabricating a memory structure in accordance with some embodiments.

FIG. 12 is a sectional view illustrating a memory structure that is fabricated using the method for fabricating a memory structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

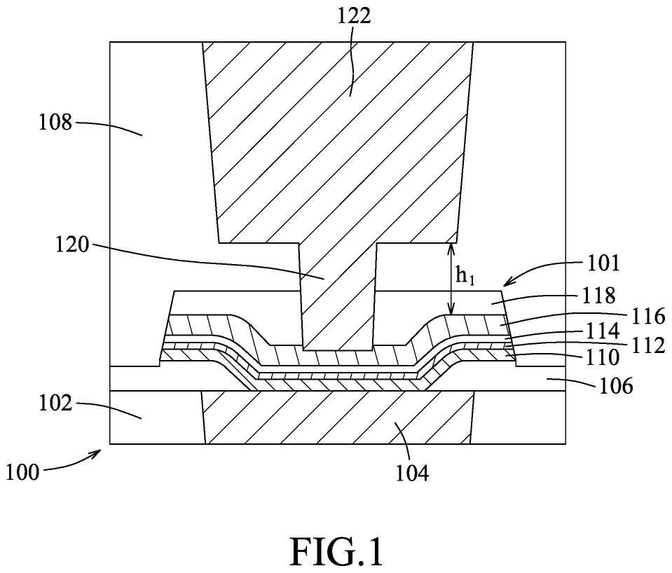

FIG. 1 illustrates a sectional view of a memory structure in accordance with a first embodiment. The memory structure includes a substrate 100, an etch stop layer 106 that is formed over the substrate 100, and a memory component 101 that is formed over the substrate 100 and the etch stop layer 106. The substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The substrate 100 may be made of a suitable semiconductor material, such as silicon or the like. In some embodiments, the substrate 100 is a silicon substrate; and in other embodiments, the substrate 100 is made of a compound semiconductor such as silicon carbide, gallium arsenide, indium arsenide, indium phosphide or other suitable materials. In still other embodiments, the substrate 100 is made of an alloy semiconductor such as GaAsP, AlInAs, AlGaAs, GaInAs, GaInP, GaInAsP or other suitable materials.

In some embodiments, the substrate 100 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The substrate 100 may include lateral isolation features (e.g., shallow trench isolation (STI)) configured to separate various functional elements formed on the substrate 100 and/or various functional elements formed in the substrate 100.

In the illustrative embodiment, the substrate 100 includes a first dielectric 102 for isolation purposes, and a first metal trench 104 formed in the first dielectric 102. The first dielectric 102 may include, for example, oxide materials (e.g., SiO₂), low-k materials (e.g., fluorinated silicon dioxide (FSG), SiCOH, polyimide, etc.), other suitable materials, or any combination thereof. The first metal trench 104 may include, for example, Cu, Ru, W, Ti, Al, Co, Mo, Ir, Rh, Ta, other suitable materials, or any combination thereof. In the illustrative embodiment, the first metal trench 104 is made of copper. During the fabrication process, the etch stop layer 106 is formed with a recess that reveals the first metal trench 104, and the memory component 101 is, at least in part, formed in the recess, so the memory component 101 is electrically connected to the first metal trench 104. In accordance with some embodiments, the etch stop layer 106 may include, for example, SiC, SiN, SiOC, oxide materials (e.g., SiO₂), other suitable materials, or any combination thereof, and may have a thickness in a range from about 50 angstroms to about 450 angstroms.

The memory component 101 is formed in a second dielectric 108, and includes a barrier layer 110, a bottom electrode 112, a data storage feature 114, a top electrode 116 and a hard mask feature 118 that are stacked in the given order from bottom to top. The second dielectric 108 may include, for example, oxide materials, low-k materials (e.g., fluorinated silicon dioxide (FSG), SiCOH, polyimide, etc.), other suitable materials, or any combination thereof, and may have a thickness in a range from about 1100 angstroms to about 2700 angstroms. The barrier layer 110 is conformally formed over a part of the etch stop layer 106 and a portion of the first metal trench 104 that is revealed from the recess of the etch stop layer 106, and is used to prevent metal elements in the first metal trench 104, such as Cu elements in this embodiment, from diffusing or migrating into the memory component 101. In accordance with some embodiments, the barrier layer 110 may include, for example, Ta, TaN, Ti, TiN, other suitable materials, or any combination thereof, and may have a thickness in a range from about 10 angstroms to about 250 angstroms. Since diffusion or migration of the metal elements from the first metal trench 104 into the memory component 101 may result in functional degradation of the memory component 101, it is important that the barrier layer 110 completely covers the portion of the first metal trench 104 that is revealed from the recess in the etch stop layer 106. The bottom electrode 112 is conformally formed over the barrier layer 110. In accordance with some embodiments, the bottom electrode 112 may include, for example, Ta, Ti, Hf, Ru, Pt, Ir, Mo, W, their nitride materials, other suitable materials, or any combination thereof, and may have a thickness in a range from about 20 angstroms to about 400 angstroms. In this embodiment, the memory component 101 is exemplified as RRAM, which is suitable for use as embedded memory because of its high-speed read and write operations, good scalability, good endurance, and good data retention, and the data storage feature 114 may include, for example, metal oxide materials, high-k materials, other suitable materials, or any combination thereof. In accordance with some embodiments, the metal oxide materials may include metal elements such as Ta, Ti, Hf, Ru, Pt, Ir, Mo, W, other suitable metal elements, or any combination thereof. In other embodiments where the memory component 101 is exemplified as other types of memory, such as MRAM, FeRAM, etc., other suitable materials may be used to form the data storage feature 114, and this disclosure is not limited in this respect. The top electrode 116 is conformally formed over the data storage feature 114. In accordance with some embodiments, the top electrode 116 may include, for example, Ta, Ti, Hf, Ru, Pt, Ir, Mo, W, their nitride materials, other suitable materials, or any combination thereof, and may have a thickness in a range from about 100 angstroms to about 500 angstroms. The hard mask feature 118 is formed over the top electrode 116, and is used as a patterning mask during the formation of the top electrode 116, the data storage feature 114, the bottom electrode 112 and the barrier layer 110. A portion of the etch stop layer 106 that is not covered by the memory component 101 may be partly removed during the etching of the barrier layer 110, and may thus be thinner than a portion of the etch stop layer 106 that is covered by the memory component 101. The hard mask feature 118 also serves as an etch stop layer during etching of the second dielectric 108 in order to form a via hole in the second dielectric 108. In accordance with some embodiments, the hard mask feature 118 may include, for example, SiC, SiN, SiOC, oxide materials, other suitable materials, or any combination thereof, and may have a thickness in a range from about 50 angstroms to about 400 angstroms. In the illustrative embodiment, the second dielectric 108 is formed with a metal via 120 and a second metal trench 122 therein, where the metal via 120 penetrates the hard mask feature 118 and extends between the second metal trench 122 and the top electrode 116, so the second metal trench 122 is electrically connected to the memory component 101. In accordance with some embodiments, each of the metal via 120 and the second metal trench 122 may include, for example, Cu, Ru, W, Ti, Al, Co, Mo, Ir, Rh, Ta, other suitable materials, or any combination thereof. In accordance with some embodiments, another barrier layer (not shown) may be formed between the metal via 120 and the top electrode 116, between the metal via 120 and the hard mask feature 118, between the metal via 120 and the second dielectric 108, and between the second metal trench 122 and the second dielectric 108, but this disclosure is not limited in this respect.

With the advancement of semiconductor technologies, a cell size of the memory structure has shrunken in length, width and height, and a distance between the second metal trench 122 and the memory component 101 is reduced (e.g., with a shorter metal via 120). The shortest distance h₁ between the second metal trench 122 and the top electrode 116 of the memory component 101 is a crucial factor in the reduction of the height of the memory structure because, when the second metal trench 122 is too close to the top electrode 116, an undesired short circuit path that passes through the second dielectric 108 and the hard mask feature 118 may be induced between the second metal trench 122 and the top electrode 116 even though the hard mask feature 118 also serves as an isolation, and thus cause degradation on performance of the memory component 101. In the illustrative embodiment, the shortest distance h₁ between the second metal trench 122 and the top electrode 116 of the memory component 101 is a distance between a bottom surface of the second metal trench 122 and a top surface of a portion of the top electrode 116 that is disposed over the etch stop layer 106, which is located at a higher position than a portion of the top electrode 116 that corresponds in position to the recess formed in the etch stop layer 106.

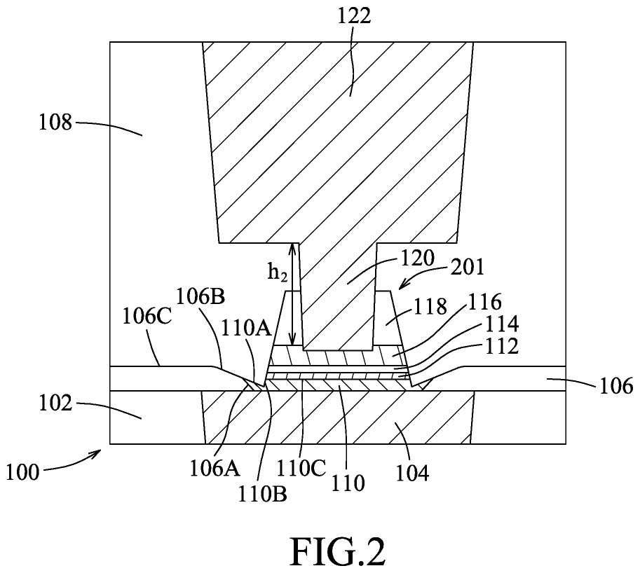

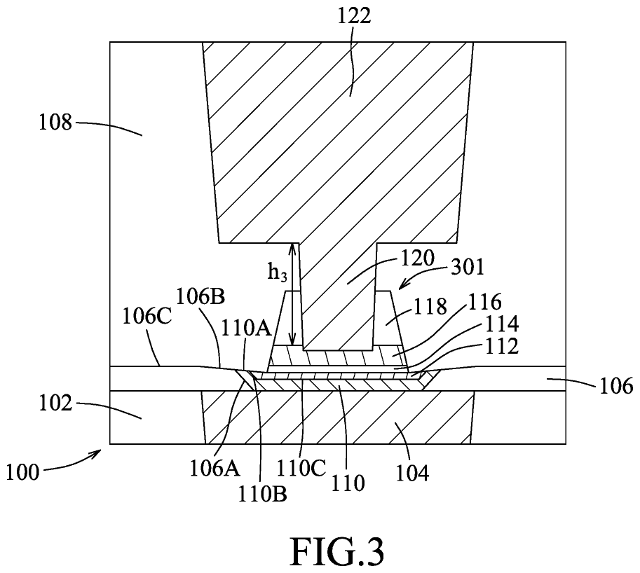

FIG. 2 and FIG. 3 illustrate sectional views of memory structures in accordance with a second embodiment and a third embodiment, respectively, where the memory structure of the second embodiment includes a memory component 201, and the memory structure of the third embodiment includes a memory component 301. The memory components 201 and 301 are similar to the memory component 101 in the first embodiment (see FIG. 1). In accordance with some embodiments, the materials introduced in the first embodiment may also be applied to the second and third embodiments, and thus are not repeated herein for the sake of brevity. The second and third embodiments differ from the first embodiment in that the memory components 201 and 301 do not extend outside the recess formed in the etch stop layer 106, namely, do not extend over a top side of the etch stop layer 106, and thus is smaller than the memory component 101 of the first embodiment in length and width. Since the memory components 201 and 301 do not extend over the etch stop layer 106, when the memory components 201 and 301 are configured to be the same as the memory component 101 in terms of thicknesses of the barrier layer 110, the bottom electrode 112, the data storage layer 114, the top electrode 116 and the metal via 120, the shortest distances h₂ between the second metal trench 122 and the top electrode 116 of the memory component 201 in the second embodiment and the shortest distances h₃ between the second metal trench 122 and the top electrode 116 of the memory component 301 in the third embodiment would be greater than that in the first embodiment (i.e., the distance h₁ in FIG. 1). Particularly, the distance h₂ as well as the distance h₃ would be greater than the distance h₁ by about a thickness of the etch stop layer 106. Therefore, each of the second embodiment and the third embodiment may have a larger room for reducing the height of the memory structure or the height of the metal via 120 in comparison to the first embodiment.

In each of the second embodiment and the third embodiment, the etch stop layer 106 has a covering portion that covers an edge portion of the first metal trench 104; and the barrier layer 110 is disposed within bounds defined by the covering portion of the etch stop layer 106, and covers a middle portion of the first metal trench 104 that is not covered by the etch stop layer 106 (namely, the portion other than the covering portion or the rest of the first metal trench 104). The barrier layer 110 is sunk in the etch stop layer 106 (so the barrier layer 110 is surrounded and confined by the etch stop layer 106 in lateral directions that are parallel to the top surface of the first metal trench 104), and cooperates with the etch stop layer 106 to seal or completely cover the first metal trench 104, so as to prevent the metal elements of the first metal trench 104 from diffusing or migrating into the memory component 201 or 301. A top surface of the etch stop layer 106 has a first inclined surface portion 106A, a second inclined surface portion 106B and a horizontal surface portion 106C. The horizontal surface portion 106C extends in parallel to a top surface of the first metal trench 104. The second inclined surface portion 106B extends obliquely, relative to the top surface of the first metal trench 104, from the horizontal surface portion 106C toward the first metal trench 104. The first inclined surface portion 106A extends obliquely, relative to the top surface of the first metal trench 104, from the second inclined surface portion 106B to the first metal trench 104. In other words, the second inclined surface portion 106B extends between and interconnects the horizontal surface portion 106C and the first inclined surface portion 106A. In the illustrative embodiments of FIG. 2 and FIG. 3, an obliqueness of the second inclined surface portion 106B relative to the top surface of the first metal trench 104 is smaller than an obliqueness of the first inclined surface portion 106A relative to the top surface of the first metal trench 104 (i.e., the first inclined surface portion 106A is steeper than the second inclined surface portion 106B). The barrier layer 110 has an edge portion that is disposed over and covers the first inclined surface portion 106A of the top surface of the etch stop layer 106, and an outmost edge of the barrier layer 110 is connected to a junction between the second inclined surface portion 106B and the first inclined surface portion 106A of the top surface of the etch stop layer 106.

In the second embodiment as illustrated in FIG. 2, a top surface of the barrier layer 110 has an edge surface portion 110A, a connecting surface portion 110B, and a horizontal surface portion 110C. The horizontal surface portion 110C extends in parallel to the top surface of the first metal trench 104, and the bottom electrode 112 is completely disposed on the horizontal surface portion 110C. The edge surface portion 110A extends obliquely, relative to the top surface of the first metal trench 104, from the etch stop layer 106 toward the top surface of the first metal trench 104. The connecting surface portion 110B extends obliquely, relative to the top surface of the first metal trench 104, from an end of the horizontal surface portion 110C to an end of the edge surface portion 110A that is away from the etch stop layer 106. An obliqueness of the edge surface portion 110A relative to the top surface of the first metal trench 104 is different from that of the connecting surface portion 110B relative to the top surface of the first metal trench 104. In accordance with some embodiments, the obliqueness of the edge surface portion 110A is smaller than that of the connecting surface portion 110B relative to the top surface of the first metal trench 104 (namely, the connecting surface portion 110B is steeper than the edge surface portion 110A). In the illustrative embodiment, the edge surface portion 110A and the connecting surface portion 110B slope upwardly in opposite directions, where the connecting surface portion 110B slopes upwardly toward a center of the memory component 201, the edge surface portion 110A slopes upwardly away from the center of the memory component 201, and the end of the edge surface portion 110A which is away from the etch stop layer 106 (i.e., a junction between the edge surface portion 110A and the connecting surface portion 110B) is closer to the top surface of the first metal trench 104 in comparison to the horizontal surface portion 110C of the barrier layer 110. In the second embodiment, since the etch stop layer 106 is thicker than the barrier layer 110 and the barrier layer 110 does not extend over the horizontal surface portion 106C of the top surface of the etch stop layer 106, the horizontal surface portion 106C of the top surface of the etch stop layer 106 is higher in position than an entirety of the barrier layer 110 relative to the top surface of the first metal trench 104.

In the third embodiment as illustrated in FIG. 3, a top surface of the barrier layer 110 has an edge surface portion 110A, a connecting surface portion 110B, and a horizontal surface portion 110C. The horizontal surface portion 110C extends in parallel to the top surface of the first metal trench 104. The edge surface portion 110A extends obliquely, relative to the top surface of the first metal trench 104, from the etch stop layer 106 toward the top surface of the first metal trench 104. The connecting surface portion 110B extends obliquely, relative to the top surface of the first metal trench 104, from an end of the horizontal surface portion 110C to an end of the edge surface portion 110A which is away from the etch stop layer 106. The bottom electrode 112 is disposed on both of the horizontal surface portion 110C and the connecting surface portion 110B of the top surface of the barrier layer 110. An obliqueness of the edge surface portion 110A relative to the top surface of the first metal trench 104 is different from an obliqueness of the connecting surface portion 110B relative to the top surface of the first metal trench 104. In accordance with some embodiments, the obliqueness of the edge surface portion 110A relative to the top surface of the first metal trench 104 is smaller than that of the connecting surface portion 110B relative to the top surface of the first metal trench 104 (namely, the connecting surface portion 110B is steeper than the edge surface portion 110A). In the illustrative embodiment, the edge surface portion 110A and the connecting surface portion 110B slope upwardly toward the same direction, which is away from a center of the memory component 301, and the end of the edge surface portion 110A which is away from the etch stop layer 106 (i.e., a junction between the edge surface portion 110A and the connecting surface portion 110B) is farther from the top surface of the first metal trench 104 in comparison to the horizontal surface portion 110C of the barrier layer 110. In the third embodiment, since the etch stop layer 106 is thicker than the barrier layer 110 and the barrier layer 110 does not extend over the horizontal surface portion 106C of the top surface of the etch stop layer 106, the horizontal surface portion 106C of the top surface of the etch stop layer 106 is higher in position than an entirety of the barrier layer 110 relative to the top surface of the first metal trench 104.

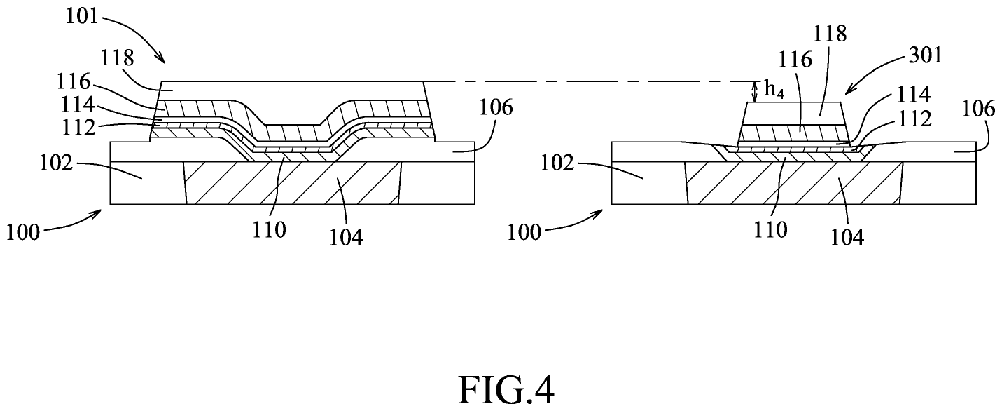

FIG. 4 illustrates a comparison between the memory structures of the first embodiment and the third embodiment, with the first embodiment being shown on the left and the third embodiment being shown on the right. It can be seen that the memory structure of the third embodiment has a smaller width and a smaller height because the memory component 301 does not extend over the etch stop layer 106. The memory component 301 is thinner than the memory component 101 by a difference h₄ that is approximately the thickness of the etch stop layer 106. The memory structure of the second embodiment has similar characteristics to the third embodiment in terms of dimensions, so comparison between the first embodiment and the second embodiment is omitted herein for the sake of brevity. The height of the memory structure may result in a step height between memory regions and logic regions (not shown) on the substrate 100, and an excessive step height may lead to issues with exposure and development in a photolithography process due to an exposure limit in terms of depth of focus (DoF). In comparison to the memory structure according to the first embodiment, the smaller heights of the memory structures according to the second and third embodiments may lead to smaller step heights between memory regions and logic regions (not shown) on the substrate 100, so additional process steps that are used for reducing or eliminating excessive step heights between memory regions and logic regions, such as deposition of an additional inter-metal dielectric and a following planarization process, may not be needed.

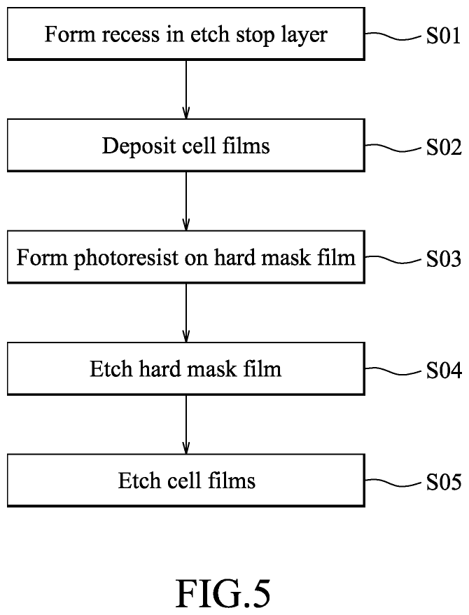

FIG. 5 illustrates steps of a method for fabricating a memory structure that includes the memory component 201 (see FIG. 2) or the memory component 301 (see FIG. 3) in accordance with some embodiments.

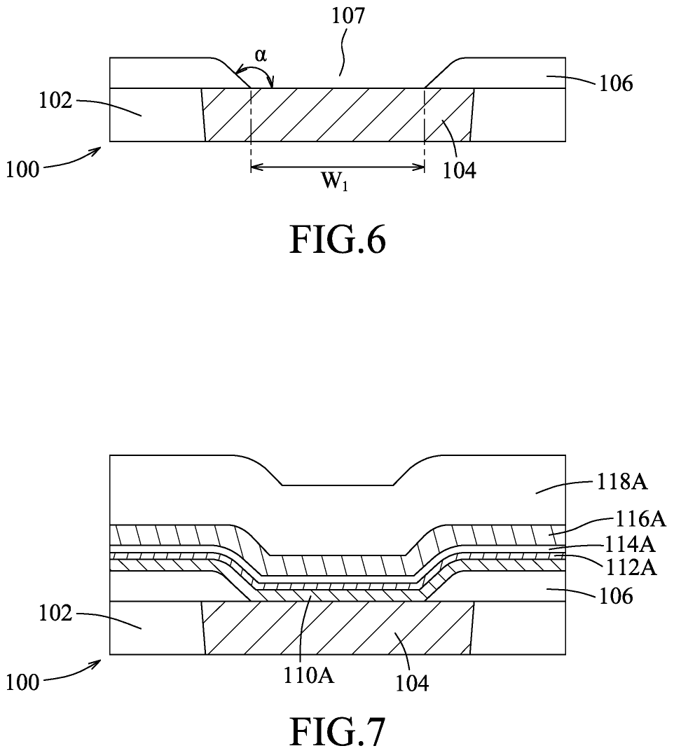

Referring to FIGS. 5 and 6, an etch stop layer 106 is deposited on a substrate 100 that includes a first dielectric 102, and a first metal trench 104 formed in the first dielectric 102, and then the etch stop layer 106 is etched to form a recess 107 therein (step S01) to expose the first metal trench 104. In accordance with some embodiments, a bottom width W₁ of the recess 107 may range from about 70% to about 90% of a width of the top surface of the first metal trench 106, so as to achieve a good overlay control of lithography process to form the recess 107, and a sufficiently large width of the resultant memory component. In accordance with some embodiments, an angle α between a sidewall of the recess 107 and a top surface of the revealed portion of the first metal trench 104 may range from about 110 degrees to about 150 degrees, so as to achieve good conformity in subsequent depositions of films that are to be stacked together, where poor conformity may lead to leakage in a data storage feature that is to be formed later. In order to form the recess 107 in the etch stop layer 106, in some embodiments, an etching mask (e.g., a patterned photoresist, not shown) may be formed over the etch stop layer 106, with a to-be-etched portion of the etch stop layer 106 being exposed from the etching mask. Then, as a first step, the etch stop layer 106 may be isotropically etched with the etching mask on top. When the exposed portion of the etch stop layer 106 is etched to achieve a specific thickness, the etching mask is removed to expose the entire etch stop layer 106, and an anisotropic etching (e.g., high bombardment etching) is performed to remove the remaining thickness of the aforesaid portion of the etch stop layer 106 to form the recess 107, and to round a corner of the etch stop layer 106. Then, blanket etching is performed to control the angle α between a sidewall of the recess 107 and a top surface of the exposed portion of the first metal trench 104.

Referring to FIGS. 5 and 7, a barrier film 110A, a bottom electrode film 112A, a data storage film 114A, a top electrode film 116A and a hard mask film 118A (collectively referred to as “cell films”) are conformally deposited over the etch stop layer 106 and the portion of the first metal trench 104 that is exposed from the recess 107 (see FIG. 6) in the given order from bottom to top (step S02), so that each of the barrier film 110A, the bottom electrode film 112A, the data storage film 114A, the top electrode film 116A and the hard mask film 118A has a recessed portion corresponding in position to the recess 107 formed in the etch stop layer 106. In accordance with some embodiments, each of the cell films may be deposited using, for example, atomic layer deposition (ALD), physical vapor deposition (PVD) at low deposition rate, chemical vapor deposition (CVD) at low deposition rate, other suitable techniques, or any combination thereof.

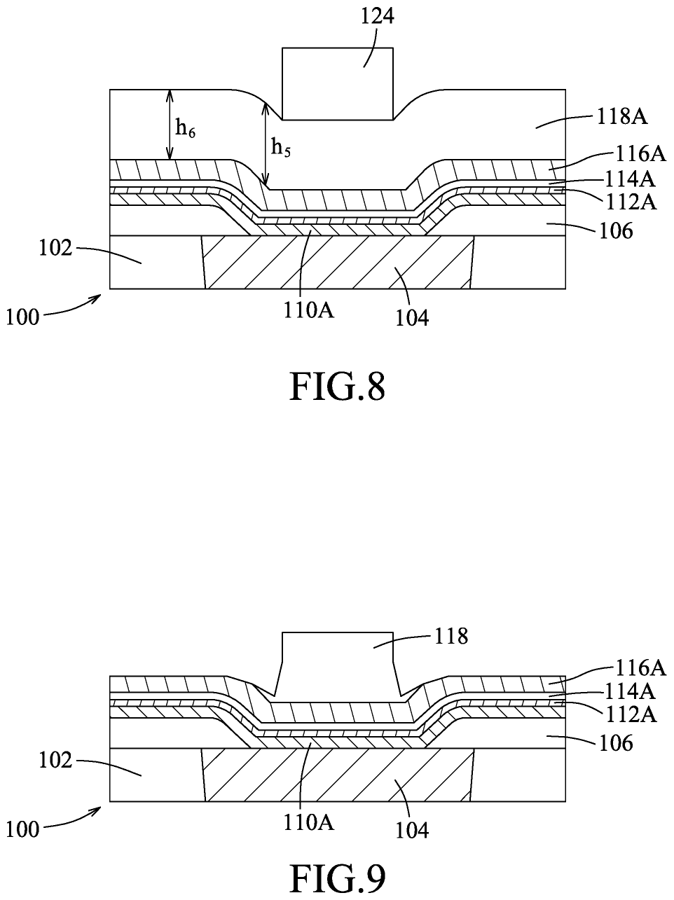

Referring to FIGS. 5 and 8, an etching mask feature 124 is formed (step S03) over the hard mask film 118A and corresponds in position to the recess 107 (see FIG. 6) formed in the etch stop layer 106 (namely, formed over the recessed portion of the hard mask film 118A), where a projection of the etching mask feature 124 onto the top surface of the first metal trench 104 falls within the recess 107. In accordance with some embodiments, the etching mask feature 124 may include, for example, a photoresist material, other suitable materials, or any combination thereof, and may be formed using, for example, a photolithography process, other suitable techniques, or any combination thereof. In accordance with some embodiments, the etching mask feature 124 may be completely formed on a bottom of the recessed portion of the hard mask film 118A. In accordance with some embodiments, the etching mask feature 124 may be formed on both of the bottom and a sidewall of the recessed portion of the hard mask film 118A.

Referring to FIGS. 5 and 9, the hard mask film 118A (see FIG. 8) is etched with the etching mask feature 124 disposed thereon (step S04) to form a hard mask feature 118 that has an edge portion connected to a sidewall of the recessed portion of the top electrode film 116A. There are two main reasons that cause the resultant hard mask feature 118 to have such an edge portion remaining at a bottom corner of the recessed portion of the top electrode film 116A after the etching of the hard mask film 118A. The first reason is that, referring to FIG. 8 again, since a vertical thickness h₅ of the hard mask film 118A at a sidewall portion is greater than a vertical thickness h₆ of the hard mask film 118A at a top horizontal portion, it is possible to control the etching process such that the sidewall portion of the hard mask film 118A partly remains after the top horizontal portion of the hard mask film 118A has been completely removed. Such a condition (i.e., a vertical thickness at a sidewall portion being greater than a vertical thickness at a top horizontal portion) may also appear in the barrier film 110A, the bottom electrode film 112A, the data storage film 114A and the top electrode film 116A. The second reason is that, since the sidewall portion of the hard mask film 118A is closer to the etching mask feature 124 in comparison to the top horizontal portion of the hard mask film 118A, the etching rate of the sidewall portion may be lower than that of the top horizontal portion because the etching mask feature 124 may block out a part of etching plasma. In accordance with some embodiments, the hard mask film 118A is etched straight down in the beginning using, for example, CF₄, other suitable etchants, or any combination thereof, in order to achieve good uniformity control in terms of critical dimension (e.g., a width of a top surface of the resultant hard mask feature 118, a width of the resultant memory component, etc.), and this process may be omitted in some embodiments. Then, additional substance(s) may be added to weaken the sidewall etching capability because the byproduct of etching, such as polymer, may accumulate on a side surface of the hard mask film 118A under etching, thereby forming an inclined sidewall portion of the hard mask feature 118. As a result, a bottom portion of the hard mask feature 118 is wider than a top portion of the hard mask feature 118.

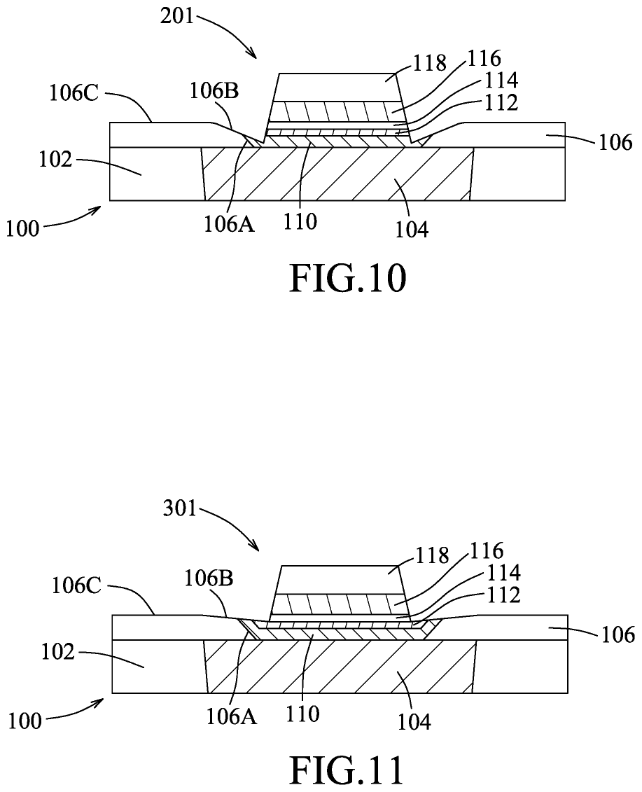

Referring to FIGS. 5, 10 and 11, the top electrode film 116A, the data storage film 114A, the bottom electrode film 112A and the barrier film 110A (see FIG. 9) are etched (step S05) with the hard mask feature 118 serving as an etching mask in such a way that the top electrode 116, the data storage feature 114, the bottom electrode 112 and the barrier layer 110 of the memory component 201 or 301 as introduced above are formed, where a width of the memory component 201 or 301, which can be deemed equivalent to a width of a top surface of the data storage feature 114, may range from about 50% to about 90% of the width of the recess 107 (see FIG. 6) formed in the etch stop layer 106 (i.e., a width of the portion of the first metal trench 104 that is not covered by the etch stop layer 106). A remaining portion of the barrier film 110A (namely, a portion of the barrier film 110A that remains after the etching of the barrier film 110A) forms the barrier layer 110 of the memory component 201, 301, is connected to the etch stop layer 106, and cooperates with the etch stop layer 106 to completely cover the first metal trench 104. The barrier layer 110 has an edge profile that copies or resembles an edge profile of the hard mask feature 118 as shown in FIG. 9. In accordance with some embodiments, the etching of these cell films may be performed using anisotropic etching that includes, for example, reactive-ion etching (RIE), inductively coupled plasma (ICP) etching, other suitable techniques, or any combination thereof. In accordance with some embodiments where the edge portion of the hard mask feature 118 (i.e., the portion that remains at the bottom corner of the recessed portion of the top electrode film 116A) as illustrated in FIG. 9 is thin, the memory component 201 as shown in FIG. 10 may be formed. In accordance with some embodiments where the edge portion of the hard mask feature 118 as illustrated in FIG. 9 is thick, the memory component 301 as shown in FIG. 11 may be formed. In both of FIGS. 10 and 11, an edge portion of a top surface of the hard mask feature 118 is not higher in position than a central portion of the top surface of the hard mask feature 118, so the memory components 201, 301 earn the benefit of a small height that leads to a larger room for reducing the height of the entire memory structure or the height of the metal via 120 (see FIGS. 2 and 3). In accordance with some embodiments, the material used in the bottom electrode film 112A may be selected such that the barrier film 100A has a high etching selectivity relative to the bottom electrode film 112A, so that a part of the bottom electrode film 112A that remains and is exposed in the recessed portion of the barrier film 110A after the etching of the bottom electrode film 112A would not be removed during the etching of the barrier film 110A, thereby forming the memory component 301 as shown in FIG. 11, and ensuring integrity of the barrier layer 110. Examples of such material of the bottom electrode film 112A include, but are not limited to, Ru, Pt, Ir, Mo, W, etc. Because the first inclined surface portion 106A of the top surface of the etch stop layer 106 is covered during the etching, the obliqueness of the first inclined surface portion 106A relative to the top surface of the first metal trench 104 substantially remains the same as an obliqueness of the sidewall of the recess 107 in FIG. 6. On the other hand, since the second inclined surface portion 106B of the top surface of the etch stop layer 106 may be exposed toward the end of the etching of the barrier film 110A (see FIG. 9), the obliqueness of the second inclined surface portion 106B is reduced as a result, and becomes smaller than that of the first inclined surface portion 106A.

After step S05, referring to FIGS. 2 and 3 again, a damascene process may be performed to form the second dielectric 108, the metal via 120 and the second metal trench 122, such that the top electrode 116 of the memory component 201, 301 is electrically connected to the second metal trench 122.

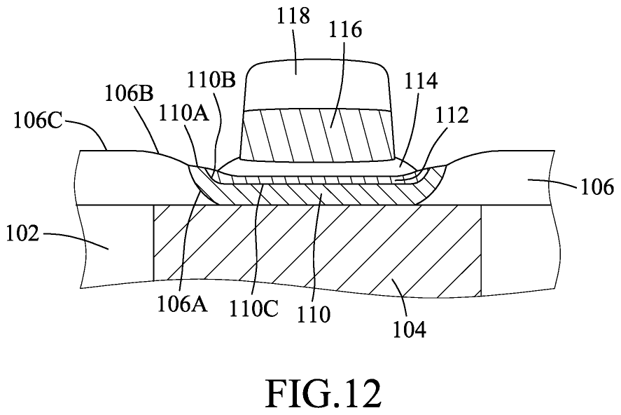

FIG. 12 is a schematic diagram depicted according to an image of a memory structure that is actually fabricated using the method as described above. The depicted memory structure corresponds to the third embodiment, where the barrier layer 110 is made to be U-shaped and is formed to have a recess, and the bottom electrode 112 is disposed in the recess of the barrier layer 110, and is connected to the connecting surface portion 110B of the top surface of the barrier layer 110, ensuring the integrity of the barrier layer 110. The top surface of the etch stop layer 106 has an abrupt change in slope (i.e., a discontinuous slope) at the junction between the first inclined surface portion 106A and the second inclined surface portion 106B.

In accordance with some embodiments, a memory structure is provided to include a substrate having a metal trench, a barrier layer disposed over the metal trench, an etch stop layer surrounding the barrier layer, a bottom electrode disposed over the barrier layer, a data storage feature disposed over the bottom electrode, and a top electrode disposed over the data storage feature. The barrier layer is sunk in the etch stop layer. The etch stop layer, together with the barrier layer, completely covers the metal trench.

In accordance with some embodiments, the barrier layer is confined by the etch stop layer in lateral directions that are parallel to a top surface of the metal trench.

In accordance with some embodiments, a top surface of the etch stop layer has a first inclined surface portion that extends obliquely from a top surface of the metal trench, and the barrier layer has an edge portion that is disposed over the first inclined surface portion of the top surface of the etch stop layer.

In accordance with some embodiments, the top surface of the etch stop layer further has a horizontal surface portion that extends in parallel to the top surface of the metal trench, and a second inclined surface portion that extends obliquely, relative to the top surface of the metal trench, from the horizontal surface portion to the first inclined surface portion of the top surface of the etch stop layer. An obliqueness of the second inclined surface portion relative to the top surface of the metal trench is smaller than an obliqueness of the first inclined surface portion relative to the top surface of the metal trench.

In accordance with some embodiments, an outmost edge of the barrier layer is connected to a junction between the second inclined surface portion and the first inclined surface portion of the top surface of the etch stop layer.

In accordance with some embodiments, a top surface of the barrier layer has a horizontal surface portion that extends in parallel to a top surface of the metal trench, an edge surface portion that extends obliquely relative to a top surface of the metal trench, from the etch stop layer toward the top surface of the metal trench, and a connecting surface portion that extends obliquely, relative to a top surface of the metal trench, from an end of the horizontal surface portion to an end of the edge surface portion which is away from the etch stop layer. An obliqueness of the edge surface portion relative to the top surface of the metal trench is different from an obliqueness of the connecting surface portion relative to the top surface of the metal trench.

In accordance with some embodiments, the end of the edge surface portion that is away from the etch stop layer is closer to the top surface of the metal trench in comparison to the horizontal surface portion.

In accordance with some embodiments, the bottom electrode is completely disposed on the horizontal surface portion of the top surface of the barrier layer.

In accordance with some embodiments, the end of the edge surface portion which is away from the etch stop layer is farther from the top surface of the metal trench in comparison to the horizontal surface portion.

In accordance with some embodiments, the bottom electrode is disposed on both of the horizontal surface portion and the connecting surface portion of the top surface of the barrier layer.

In accordance with some embodiments, a memory structure is provided to include a substrate having a metal trench, an etch stop layer disposed over the substrate and having a covering portion that covers an edge portion of the metal trench, a barrier layer disposed within bounds that are defined by the covering portion of the etch stop layer and covering a remaining portion of the metal trench other than the edge portion, a bottom electrode disposed over the barrier layer, a data storage feature disposed over the bottom electrode, and a top electrode disposed over the data storage feature.

In accordance with some embodiments, the barrier layer covers a portion of the etch stop layer.

In accordance with some embodiments, a top surface of the etch stop layer has a horizontal surface portion that extends in parallel to a top surface of the metal trench, and that is higher in position than an entirety of the barrier layer relative to the top surface of the metal trench.

In accordance with some embodiments, the top surface of the etch stop layer further has a first inclined surface portion that extends obliquely from the top surface of the metal trench, and the barrier layer has an edge portion that is disposed over the first inclined surface portion of the top surface of the etch stop layer.

In accordance with some embodiments, the top surface of the etch stop layer further has a second inclined surface portion that extends obliquely, relative to the top surface of the metal trench, from the horizontal surface portion to the first inclined surface portion of the top surface of the etch stop layer. An obliqueness of the second inclined surface portion relative to the top surface of the metal trench is smaller than that of the first inclined surface portion relative to the top surface of the metal trench.

In accordance with some embodiments, an outmost edge of the barrier layer is connected to a junction between the second inclined surface portion and the first inclined surface portion of the top surface of the etch stop layer.

In accordance with some embodiments, a top surface of the barrier layer has a horizontal surface portion that extends in parallel to a top surface of the metal trench, an edge surface portion that extends obliquely, relative to the top surface of the metal trench, from the etch stop layer toward the top surface of the metal trench, and a connecting surface portion that extends obliquely, relative to the top surface of the metal trench, from an end of the horizontal surface portion to an end of the edge surface portion which is away from the etch stop layer. The bottom electrode is completely disposed on the horizontal surface portion of the top surface of the barrier layer.

In accordance with some embodiments, a top surface of the barrier layer has a horizontal surface portion that extends in parallel to a top surface of the metal trench, an edge surface portion that extends obliquely, relative to the top surface of the metal trench, from the etch stop layer toward the top surface of the metal trench, and a connecting surface portion that extends obliquely, relative to the top surface of the metal trench, from an end of the horizontal surface portion to an end of the edge surface portion which is away from the etch stop layer. The bottom electrode is disposed on both of the horizontal surface portion and the connecting surface portion of the top surface of the barrier layer.

In accordance with some embodiments, a method for fabricating a memory structure is provided. In one step, an etch stop layer is formed over a substrate that is formed with a metal trench. In one step, a recess is formed in the etch stop layer to expose a portion of the metal trench. In one step, a barrier film, a bottom electrode film, a data storage film, a top electrode film and a hard mask film are conformally formed in the given order over the etch stop layer and the portion of the metal trench, so that each of the barrier film, the bottom electrode film, the data storage film, the top electrode film and the hard mask film has a recessed portion corresponding in position to the recess formed in the etch stop layer. In one step, an etching mask feature is formed over the recessed portion of the hard mask film, wherein a projection of the etching mask feature onto a top surface of the metal trench falls within the recess. In one step, the hard mask film is etched with the etching mask feature disposed thereon to form a hard mask feature that has an edge portion connected to a sidewall of the recessed portion of the top electrode film. In one step, the top electrode film, the data storage film, the bottom electrode film and the barrier film are etched with the hard mask feature serving as an etching mask in such a way that a portion of the barrier film that remains after the etching of the barrier film is connected to the etch stop layer and, together with the etch stop layer, completely covers the metal trench.

In accordance with some embodiments, a bottom portion of the hard mask feature is wider than a top portion of the hard mask feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory structure, comprising:
a substrate having a metal trench;
a barrier layer disposed over the metal trench;
an etch stop layer surrounding the barrier layer, and, together with the barrier layer, completely covering the metal trench, the barrier layer being sunk in the etch stop layer;
a bottom electrode disposed over the barrier layer;
a data storage feature disposed over the bottom electrode; and
a top electrode disposed over the data storage feature.

2. The memory structure according to claim 1, wherein the barrier layer is confined by the etch stop layer in lateral directions that are parallel to a top surface of the metal trench.

3. The memory structure according to claim 1, wherein a top surface of the etch stop layer has a first inclined surface portion that extends obliquely from a top surface of the metal trench, and the barrier layer has an edge portion that is disposed over the first inclined surface portion of the top surface of the etch stop layer.

4. The memory structure according to claim 3, wherein the top surface of the etch stop layer further has a horizontal surface portion that extends in parallel to the top surface of the metal trench, and a second inclined surface portion that extends obliquely, relative to the top surface of the metal trench, from the horizontal surface portion to the first inclined surface portion of the top surface of the etch stop layer; and
wherein an obliqueness of the second inclined surface portion relative to the top surface of the metal trench is smaller than an obliqueness of the first inclined surface portion relative to the top surface of the metal trench.

5. The memory structure according to claim 4, wherein an outmost edge of the barrier layer is connected to a junction between the second inclined surface portion and the first inclined surface portion of the top surface of the etch stop layer.

6. The memory structure according to claim 1, wherein a top surface of the barrier layer has a horizontal surface portion that extends in parallel to a top surface of the metal trench, an edge surface portion that extends obliquely relative to a top surface of the metal trench, from the etch stop layer toward the top surface of the metal trench, and a connecting surface portion that extends obliquely, relative to a top surface of the metal trench, from an end of the horizontal surface portion to an end of the edge surface portion which is away from the etch stop layer; and
wherein an obliqueness of the edge surface portion relative to the top surface of the metal trench is different from an obliqueness of the connecting surface portion relative to the top surface of the metal trench.

7. The memory structure according to claim 6, wherein the end of the edge surface portion that is away from the etch stop layer is closer to the top surface of the metal trench in comparison to the horizontal surface portion.

8. The memory structure according to claim 6, wherein the bottom electrode is completely disposed on the horizontal surface portion of the top surface of the barrier layer.

9. The memory structure according to claim 6, wherein the end of the edge surface portion which is away from the etch stop layer is farther from the top surface of the metal trench in comparison to the horizontal surface portion.

10. The memory structure according to claim 6, wherein the bottom electrode is disposed on both of the horizontal surface portion and the connecting surface portion of the top surface of the barrier layer.

11. A memory structure, comprising:
a substrate having a metal trench;
an etch stop layer disposed over the substrate, and having a covering portion that covers an edge portion of the metal trench;
a barrier layer disposed within bounds that are defined by the covering portion of the etch stop layer, and covering a remaining portion of the metal trench other than the edge portion;
a bottom electrode disposed over the barrier layer;
a data storage feature disposed over the bottom electrode; and
a top electrode disposed over the data storage feature.

12. The memory structure according to claim 11, wherein the barrier layer covers a portion of the etch stop layer.

13. The memory structure according to claim 11, wherein a top surface of the etch stop layer has a horizontal surface portion that extends in parallel to a top surface of the metal trench, and that is higher in position than an entirety of the barrier layer relative to the top surface of the metal trench.

14. The memory structure according to claim 13, wherein the top surface of the etch stop layer further has a first inclined surface portion that extends obliquely from the top surface of the metal trench, and the barrier layer has an edge portion that is disposed over the first inclined surface portion of the top surface of the etch stop layer.

15. The memory structure according to claim 14, wherein the top surface of the etch stop layer further has a second inclined surface portion that extends obliquely, relative to the top surface of the metal trench, from the horizontal surface portion to the first inclined surface portion of the top surface of the etch stop layer; and
wherein an obliqueness of the second inclined surface portion relative to the top surface of the metal trench is smaller than that of the first inclined surface portion relative to the top surface of the metal trench.

16. The memory structure according to claim 15, wherein an outmost edge of the barrier layer is connected to a junction between the second inclined surface portion and the first inclined surface portion of the top surface of the etch stop layer.

17. The memory structure according to claim 11, wherein a top surface of the barrier layer has a horizontal surface portion that extends in parallel to a top surface of the metal trench, an edge surface portion that extends obliquely, relative to the top surface of the metal trench, from the etch stop layer toward the top surface of the metal trench, and a connecting surface portion that extends obliquely, relative to the top surface of the metal trench, from an end of the horizontal surface portion to an end of the edge surface portion which is away from the etch stop layer; and
wherein the bottom electrode is completely disposed on the horizontal surface portion of the top surface of the barrier layer.

18. The memory structure according to claim 11, wherein a top surface of the barrier layer has a horizontal surface portion that extends in parallel to a top surface of the metal trench, an edge surface portion that extends obliquely, relative to the top surface of the metal trench, from the etch stop layer toward the top surface of the metal trench, and a connecting surface portion that extends obliquely, relative to the top surface of the metal trench, from an end of the horizontal surface portion to an end of the edge surface portion which is away from the etch stop layer; and
wherein the bottom electrode is disposed on both of the horizontal surface portion and the connecting surface portion of the top surface of the barrier layer.

19. A method for fabricating a memory structure, comprising:
forming an etch stop layer over a substrate that is formed with a metal trench;
forming a recess in the etch stop layer to expose a portion of the metal trench;
conformally forming a barrier film, a bottom electrode film, a data storage film, a top electrode film and a hard mask film in the given order over the etch stop layer and the portion of the metal trench, so that each of the barrier film, the bottom electrode film, the data storage film, the top electrode film and the hard mask film has a recessed portion corresponding in position to the recess formed in the etch stop layer;
forming an etching mask feature over the recessed portion of the hard mask film, wherein a projection of the etching mask feature onto a top surface of the metal trench falls within the recess;
etching the hard mask film with the etching mask feature disposed thereon to form a hard mask feature that has an edge portion connected to a sidewall of the recessed portion of the top electrode film; and
etching the top electrode film, the data storage film, the bottom electrode film and the barrier film with the hard mask feature serving as an etching mask in such a way that a portion of the barrier film that remains after the etching of the barrier film is connected to the etch stop layer and, together with the etch stop layer, completely covers the metal trench.

20. The method according to claim 19, wherein a bottom portion of the hard mask feature is wider than a top portion of the hard mask feature.
